(19) United States
(12) Patent Application Publication
(10) Pub. No.: US 2019/0107961 A1
(43) Pub. Date: Apr. 11, 2019

(54) MEMORY SYSTEM AND OPERATING METHOD OF THE SAME

(71) Applicant: SK hynix Inc., Gyeonggi-do (KR)

(72) Inventor: Jong-Min LEE, Seoul (KR)

(21) Appl. No.: 15/993,092

(22) Filed: May 30, 2018

(30) Foreign Application Priority Data
Oct. 11, 2017 (KR) 10-2017-0129818

(51) Int. Cl. G06F 3/06

(52) U.S. Cl. CPC G06F 3/0619; G06F 3/064; G11C 16/0483; G06F 3/0679; G06F 3/0652

(57) ABSTRACT

A memory system includes: a memory device that includes a plurality of memory blocks, each of which includes a plurality of pages that store data; and a controller suitable for checking erase states of the plurality of memory blocks, performing a foreground operation and a background operation on the plurality of memory blocks based on the erase states, and storing the erase states in the plurality of memory blocks as checkpoint information.

### CROSS-REFERENCE TO RELATED APPLICATION(S)

The present application claims priority of Korean Patent Application No. 10-2017-0129818, filed on Oct. 11, 2017, which is incorporated herein by reference in its entirety.

### BACKGROUND

### 1. Field

Various embodiments of the present invention generally relate to a memory system. Particularly, the embodiments relate to a memory system capable of processing data to and from a memory device, and an operating method thereof.

### 2. Description of the Related Art

The computer environment paradigm is shifting towards ubiquitous computing, which allows users to use computer systems anytime and anywhere. As a result, the demand for portable electronic devices such as mobile phones, digital cameras, and laptop computers is increasing. These portable electronic devices generally use a memory system including one or more memory devices for storing data. A memory system may be used as a main memory device or an auxiliary memory device of a portable electronic device.

Memory systems provide excellent stability, durability, high information access speed, and low power consumption since they have no moving parts. Examples of memory systems having such advantages include universal serial bus (USB) memory devices, memory cards having various interfaces, and solid state drives (SSD).

### SUMMARY

Embodiments of the present invention are directed to a memory system capable of processing data with a memory device quickly and stably by minimizing the complexity and performance deterioration of the memory system and maximizing the utility efficiency of the memory device, and an operating method of the memory system.

In accordance with an embodiment of the present invention, a memory system includes: a memory device that includes a plurality of memory blocks, each of which includes a plurality of pages that store data; and a controller suitable for checking erase states of the plurality of memory blocks, performing a foreground operation and a background operation on the plurality of memory blocks based on the erase states, and storing the erase states in the plurality of memory blocks as checkpoint information.

The controller may check erase voltage distribution or erase voltage offset distribution of a monitoring zone set in each of the plurality of memory blocks and check the erase states through the respective erase voltage distribution or the erase voltage offset distribution.

The monitoring zone may be set in a last word line among a plurality of word lines included in each of the plurality of memory blocks or in a last page among a plurality of pages in each of the plurality of memory blocks.

The controller may perform a read operation through a change of a read voltage in the monitoring zone of each of the plurality of memory blocks, and check the erase voltage distributions in the plurality of memory blocks or the erase voltage offset distributions in the plurality of memory blocks through the read operation.

The controller may provide an erase check command for the monitoring zone of each of the plurality of memory blocks to the memory device, and check the erase voltage distribution or the erase voltage offset distributions in the plurality of memory blocks through the erase check commands.

The controller may copy data stored in first memory blocks among the plurality of memory blocks into second memory blocks, based on the respective erase voltage distributions or the erase voltage offset distributions in the first memory blocks.

The controller may process the first memory blocks as closed memory blocks, and perform program operations corresponding to write commands on the second memory blocks in response to receiving the write commands for the first memory blocks.

The controller may store data corresponding to write commands in first memory blocks among the plurality of memory blocks, based on the erase voltage distributions or the erase voltage offset distributions in the first memory blocks.

After performing erase operations corresponding to erase commands on first memory blocks among the plurality of memory blocks, the controller may check the erase states in the first memory blocks, and before performing program operations corresponding to write commands on second memory blocks, the controller may check the erase states in the second memory blocks.

The controller may check the erase states in the plurality of memory blocks after the memory system changes from a power-off state to a power-on state.

In accordance with an embodiment of the present invention, an operating method of a memory system includes: in a memory device that includes a plurality of memory blocks each of which includes a plurality of pages that store data, checking erase states of the plurality of memory blocks; performing a foreground operation and a background operation on the plurality of the memory blocks based on the erase states; and storing the erase states in the plurality of memory blocks as checkpoint information.

The checking of the erase states of the plurality of memory blocks may include: checking erase voltage distribution or erase voltage offset distribution of a monitoring zone set in each of plurality of the memory blocks; and checking the erase states through the respective erase voltage distributions or the erase voltage offset distributions.

The monitoring zone may be set in a last word line among a plurality of word lines in each of the plurality of memory blocks or in a last page among a plurality of pages in each of the plurality of memory blocks.

The checking of the erase voltage distribution or the erase voltage offset distribution may include: performing a read operation through a change of a read voltage in the monitoring zone of each of the plurality of memory blocks; and checking the erase voltage distribution or the erase voltage offset distribution of each of the plurality of memory blocks through the corresponding read operation.

The checking of the erase voltage distribution or the erase voltage offset distribution may include: providing erase check commands for the monitoring zone to the memory device; and checking the erase voltage distributions or the erase voltage offset distributions through erase check commands.

The performing of the foreground operation and the background operation on the plurality of memory blocks based on the erase states may include: copying and storing data stored in first memory blocks among the plurality of memory blocks into second memory blocks, based on the respective erase voltage distributions or the erase voltage offset distributions in the first memory blocks.

The performing of the foreground operation and the background operation on the plurality of memory blocks based on the erase states may include: processing the first memory blocks as closed memory blocks; and performing program operations corresponding to write commands on the second memory blocks in response to receiving the write commands for the first memory blocks.

The performing of the foreground operation and the background operation on the plurality of memory blocks based on the erase states may include: storing data corresponding to write commands in first memory blocks among the plurality of memory blocks, based on the erase voltage distributions or the erase voltage offset distributions in the first memory blocks.

The checking of the erase states of the plurality of memory blocks may include: after performing erase operations based on erase commands on first memory blocks among the plurality of memory blocks, checking the erase states in the first memory blocks; and before performing program operations corresponding to write commands on second memory blocks, checking the erase states in the second memory blocks.

The checking of the erase states of the plurality of memory blocks may include: checking the erase states in the plurality of memory blocks after the memory system changes from a power-off state to a power-on state.

In accordance with an embodiment of the present invention, a memory system includes: a memory device including at least one memory block having a monitoring zone; and a controller suitable for controlling, when an erase voltage distribution of the monitoring zone is below a threshold, the memory device to copy data of the memory block into a normal memory block and to close the memory block, wherein the controller stores information of the erase voltage distribution of the monitoring zone as checkpoint information.

### BRIEF DESCRIPTION OF THE DRAWINGS

FIG. 1 is a block diagram illustrating a data processing system in accordance with an embodiment of the present invention.

FIG. 2 is a schematic diagram illustrating an exemplary configuration of a memory device employed in a memory system of FIG. 1.

FIG. 3 is a circuit diagram illustrating an exemplary configuration of a memory cell array of a memory block in a memory device shown in FIG. 1.

FIG. 4 is a schematic diagram illustrating an exemplary three-dimensional (3D) structure of the memory device shown in FIG. 2.

FIGS. 5 to 7 illustrate an example of a data processing operation when a plurality of command operations, corresponding to a plurality of commands, are performed in a memory system in accordance with an embodiment of the present invention.

FIG. 8 is a flowchart describing an operation process of processing data in a memory system in accordance with an embodiment of the present invention.

FIGS. 9 to 17 are diagrams schematically illustrating application examples of the data processing system in accordance with various embodiments of the present invention.

### DETAILED DESCRIPTION

Various embodiments of the present invention are described below in more detail with reference to the accompanying drawings. However, elements and features of the present invention may be configured or arranged differently than shown in the described and illustrated embodiments, as will be apparent to those skilled in the art in light of this disclosure. Thus, the present invention is not limited to the embodiments set forth herein. Rather, the described embodiments are provided so that this disclosure is thorough and complete and fully conveys the present invention to those skilled in the art to which this invention pertains. Moreover, reference to “an embodiment” does not necessarily mean only one embodiment, and different references to “an embodiment” are not necessarily to the same embodiment(s). Throughout the disclosure, like reference numerals refer to like parts throughout the various figures and embodiments of the present invention.

It will be understood that, although the terms “first”, “second”, “third”, and so on may be used herein to identify various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to clearly illustrate various features of the embodiments.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments and is not intended to limit the present invention. As used herein, singular forms are intended to include the plural forms and vice versa, unless the context clearly indicates otherwise. It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention pertains in view of the present disclosure. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail n order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

Various embodiments of the present invention will be described in detail with reference to the attached drawings.

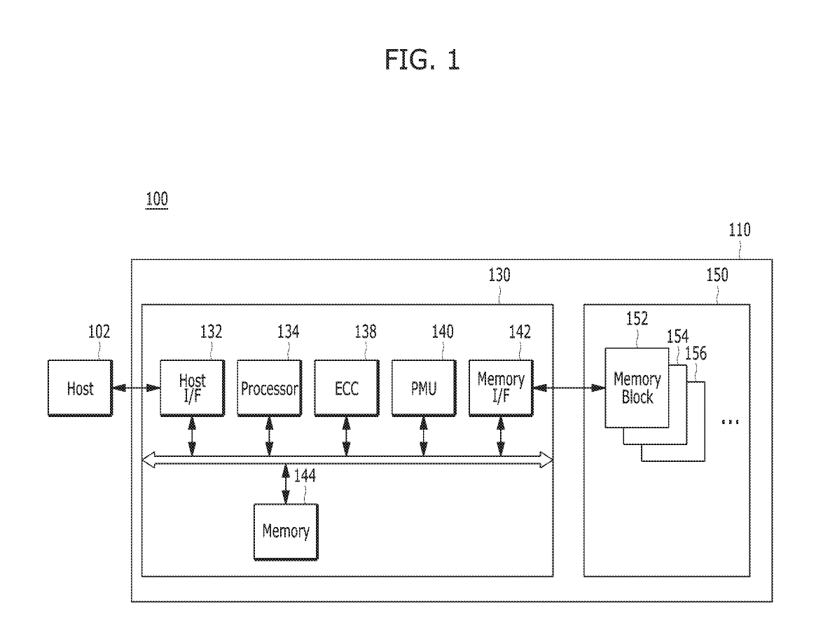

FIG. 1 is a block diagram illustrating a data processing system 100 in accordance with an embodiment of the present invention.

Referring to FIG. 1, the data processing system 100 may include a host 102 operatively coupled to a memory system 110.

The host 102 may include portable electronic devices such as a mobile phone, MP3 player and laptop computer or non-portable electronic devices such as, a desktop computer, game machine, TV, and projector.

The host 102 may include at least one operating system (OS), and the OS may manage and control overall functions and operations of the host 102, and provide an operation between the host 102 and a user using the data processing system 100 or the memory system 110. The OS may support functions and operations corresponding to the use purpose and usage of a user. For example, the OS may be divided into a general OS and a mobile OS, depending on the mobility of the host 102. The general OS may be divided into a personal OS and an enterprise OS, depending on the environment of a user. For example, the personal OS configured to support a function of providing a service to general users may include Windows and Chrome, and the enterprise OS configured to secure and support high performance may include Windows server, Linux and Unix. Furthermore, the mobile OS configured to support a function of providing a mobile service to users and a power saving function of a system may include Android, iOS and Windows Mobile. The host 102 may include a plurality of OSs, and execute an OS to perform an operation corresponding to a user's request on the memory system 110.

The memory system 110 may operate to store data for the host 102 in response to a request of the host 102. Non-limited examples of the memory system 110 may include a solid state drive (SSD), a multi-media card (MMC), a secure digital (SD) card, a universal storage bus (USB) device, a universal flash storage (UFS) device, compact flash (CF) card, a smart media card (SMC), a personal computer memory card international association (PCMCIA) card and memory stick. The MMC may include an embedded MMC (eMMC), reduced size MMC (RS-MMC) and micro-MMC, and the like. The SD card may include a mini-SD card and micro-SD card.

The memory system 110 may be embodied by any of various types of storage devices. Non -limited examples of storage devices included in the memory system 110 may include volatile memory devices such as a DRAM dynamic random access memory (DRAM) and a static RAM (SRAM) and nonvolatile memory devices such as a read only memory (ROM), a mask ROM (MROM), a programmable ROM (PROM), an erasable programmable ROM (EPROM), an electrically erasable programmable ROM (EEPROM), a ferroelectric RAM (FRAM), a phase-change RAM (PRAM), a magneto-resistive RAM (MRAM), resistive RAM (RRAM), and a flash memory.

The memory system 110 may include a memory device 150 and a controller 130. The memory device 150 may store data for the host 102, and the controller 130 may control data storage into the memory device 150.

The controller 130 and the memory device 150 may be integrated into a single semiconductor device, which may be included in any of the various types of memory systems as exemplified above.

For example, the controller 130 and the memory device 150 may be integrated as one semiconductor device to constitute an SSD. When the memory system 110 is used as an SSD, the operating speed of the host 102 connected to the memory system 110 can be improved. In addition, the controller 130 and the memory device 150 may be integrated as one semiconductor device to constitute a memory card. For example, the controller 130 and the memory device 150 may constitute a memory card such as a PCMCIA (personal computer memory card international association) card, CF card, SMC (smart media card), memory stick, MMC including RS-MMC and micro-MMC, SD card including mini-SD, micro-SD and SDHC, or UFS device.

Non-limited application exam pies of the memory system 110 may include a computer, an Ultra Mobile PC (UMPC), a workstation, a net-book, a Personal Digital Assistant (PDA), a portable computer, a web tablet, a tablet computer, a wireless phone, a mobile phone, a smart phone, an e-book, a Portable Multimedia Player (PMP), a portable game machine, a navigation system, a black box, a digital camera, a Digital Multimedia Broadcasting (DMB) player, a 3-dimensional television, a smart television, a digital audio recorder, a digital audio player, a digital picture recorder, a digital picture player, a digital video recorder, a digital video player, a storage device constituting a data center, a device capable of transmitting/receiving information in a wireless environment, one of various electronic devices constituting a home network, one of various electronic devices constituting a computer network, one of various electronic devices constituting a telematics network, a Radio Frequency Identification (RFID) device, or one of various components constituting a computing system.

The memory device 150 may be a nonvolatile memory device and may retain data stored therein even though power is not supplied. The memory device 150 may store data provided from the host 102 through a write operation, and provide data stored therein to the host 102 through a read operation. The memory device 150 may include a plurality of memory blocks 152, 154, 156 . . . (hereinafter, referred to as “memory blocks 152 to 156”), each of which may include a plurality of pages, and each of the pages may include a plurality of memory cells coupled to a word line. In an embodiment, the memory device 150 may be a flash memory. The flash memory may have a 3-dimensional (3D) stack structure.

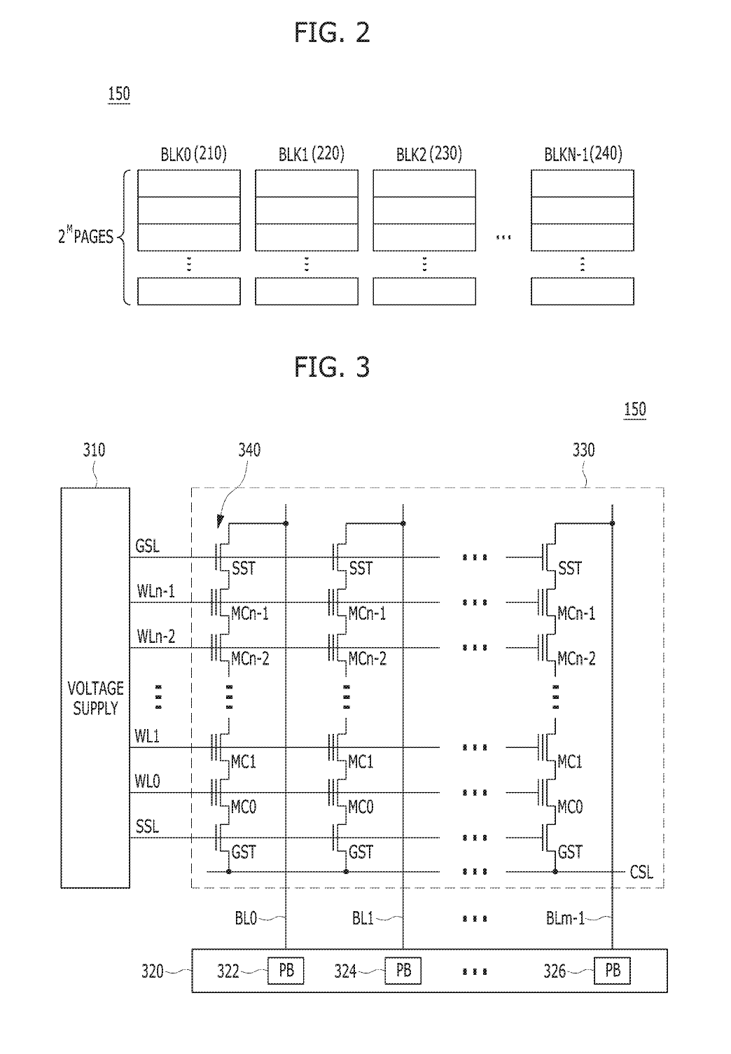

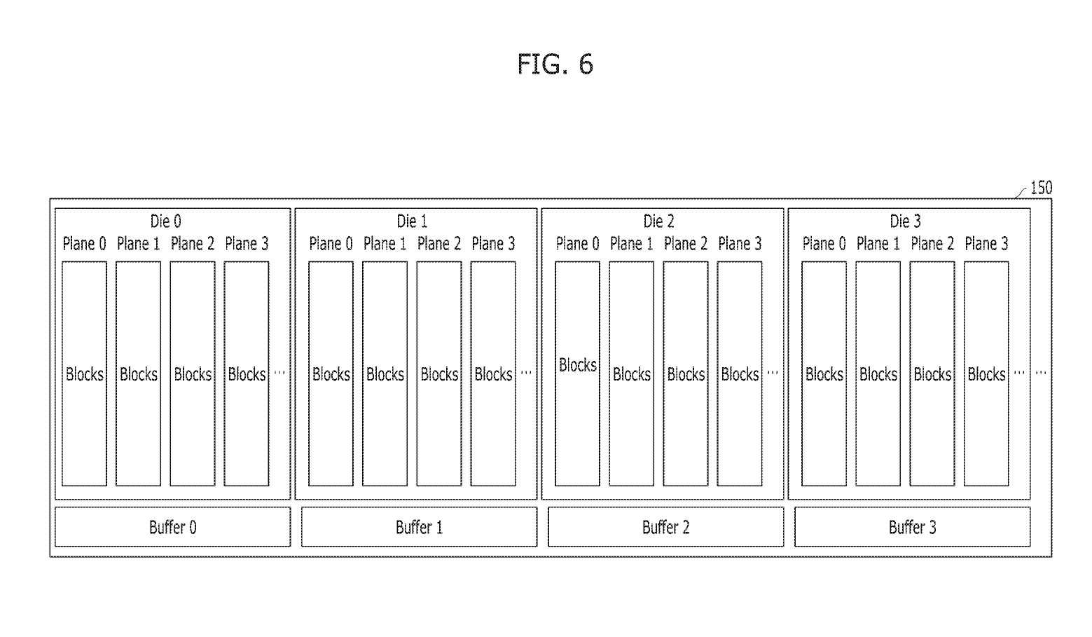

The structure of the memory device 150 including the 3D stack structure will be described in detail later with reference to FIGS. 2 to 4, and the memory device 150 including a plurality of memory dies, each of which includes a plurality of planes, each of which includes a plurality of memory blocks 152 to 156 will be described in detail later with reference to FIG. 6. Accordingly, further description of these elements and features are omitted immediately below.

The controller 130 may control the memory device 150 in response to a request from the host 102. For example, the controller 130 may provide data read from the memory device 150 to the host 102, and store data provided from the host 102 into the memory device 150. For this operation, the controller 130 may control read, write, program, and erase operations of the memory device 150.

The controller 130 may include a host interface (I/F) 132, a processor 134, an error correction code (ECC) component 138, a Power Management Unit (PMU) 140, a memory interface (I/F) 142 such as a NAND flash controller (NFC), and a memory 144 all operatively coupled via an internal bus.

The host interface 132 may process a command and data of the host 102, and may communicate with the host 102 through one or more of various interface protocols such as universal serial bus (USB), multi-media card (MMC), peripheral component interconnect-express (PCI-E), small computer system interface (SCSI), serial-attached SCSI (SAS), serial advanced technology attachment (SATA), parallel advanced technology attachment (DATA), enhanced small disk interface (ESDI) and integrated drive electronics (IDE). The host interface unit 132 may be driven via a firmware, that is, a host interface layer (HIL) for exchanging data with the host 102.

The ECC component 138 may detect and correct an error contained in the data read from the memory device 150. In other words, the ECC component 138 may perform an error correction decoding process to the data read from the memory device 150 through an ECC code used during an ECC encoding process. According to a result of the error correction decoding process, the ECC component 138 may output a signal, for example, an error correction success/fail signal. When the number of error bits is more than a threshold value of correctable error bits, the ECC component 138 may not correct the errorbits, and may output an error correction fail signal.

The ECC component 138 may perform error correction through a coded modulation such as Low Density Parity Check (LDPC) code, Bose-Chaudhri-Hocquenghem (BCH) code, turbo code, Reed-Solomon code, convolution code, Recursive Systematic Code (RSC), Trellis-Coded Modulation (TCM) and/or Block coded modulation (BCM). However, the ECC component 138 is not limited to these error correction techniques; any suitable error correction technique may be used. As such, the ECC component 138 may include all circuits, modules, systems or devices for error correction.

The PMU 140 may provide and manage power of the controller 130.

The memory interface 142 may serve as a memory/storage interface for interfacing the controller 130 and the memory device 150 such that the controller 130 controls the memory device 150 in response to a request from the host 102. When the memory device 150 is a flash memory or specifically a NAND flash memory, the memory interface 142 may generate a control signal for the memory device 150 and process data to be provided to the memory device 150 under the control of the processor 134. The memory interface 142 may work as an interface (e.g., a NAND flash interface) for processing a command and data between the controller 130 and the memory device 150. Specifically, the memory interface 142 may support data transfer between the controller 130 and the memory device 150. The memory interface unit 142 may be driven via a firmware, that is, a flash interface layer (FIL) for exchanging data with the memory device 150.

The memory 144 may serve as a working memory of the memory system 110 and the controller 130, and store data for driving the memory system 110 and the controller 130. The controller 130 may control the memory device 150 to perform read, write, program, and erase operations in response to a request from the host 102. The controller 130 may provide data read from the memory device 150 to the host 102, may store data provided from the host 102 into the memory device 150. The memory 144 may store data required for the controller 130 and the memory device 150 to perform these operations.

The memory 144 may be embodied by a volatile memory. For example, the memory 144 may be embodied by static random access memory (SRAM) or dynamic random access memory (DRAM). The memory 144 may be disposed within or out of the controller 130. FIG. 1 exemplifies the memory 144 disposed within the controller 130. In an embodiment, the memory 144 may be embodied by an external volatile memory having a memory interface transferring data between the memory 144 and the controller 130.

As described above, the memory 144 may include a program memory, a data memory, a write buffer/cache, a read buffer/cache, a data buffer/cache and a map buffer/cache to store data required to perform data write and read operations between the host 102 and the memory device 150 and data required for the controller 130 and the memory device 150 to perform these operations.

The processor 134 may control the overall operations of the memory system 110. The processor 134 may drive firmware to control the overall operations of the memory system 110. The firmware may be referred to as flash translation layer (FTL). Also, the processor 134 may be realized as a microprocessor or a Central Processing Unit (CPU).

For example, the controller 130 may perform an operation requested by the host 102 in the memory device 150 through the processor 134, which is realized as a microprocessor or a CPU. In other words, the controller 130 may perform a command operation corresponding to a command received from the host 102 or other external device. The controller 130 may perform a foreground operation as the command operation corresponding to the received command. For example, the controller 130 may perform a program operation corresponding to a write command, a read operation corresponding to a read command, an erase operation corresponding to an erase command, and a parameter set operation corresponding to a set parameter command or a set feature command as a set command.

Also, the controller 130 may perform various background operations on the memory device 150 through the processor 134, which is realized as a microprocessor or a CPU. Such background operations may include an operation of copying and processing data stored in some memory blocks among the memory blocks 152 to 156 into other memory blocks, e.g., a garbage collection (GC) operation, an operation of performing swapping between the memory blocks 152 to 156 or between the data of the memory blocks 152 to 156, e.g., a wear-leveling (WL) operation, an operation of storing the map data stored in the controller 130 in the memory blocks 152 to 156, e.g., a map flush operation, or an operation of managing bad blocks, e.g., a bad block management operation of detecting and processing bad blocks among the memory blocks 152 to 156.

Also, in the memory system in accordance with an embodiment of the present invention, the controller 130 may perform a plurality of command operations corresponding to a plurality of commands, e.g., a plurality of program operations corresponding to a plurality of write commands, a plurality of read operations corresponding to a plurality of read commands, and a plurality of erase operations corresponding to a plurality of erase commands, in the memory device 150, and update metadata, particularly, map data, according to the performance of the command operations.

In particular, in the memory system in accordance with an embodiment of the present invention, when the controller 130 performs command operations corresponding to a plurality of commands, e.g., program operations, read operations, and erase operations, in the memory blocks, the operation reliability of the memory device 150 may be deteriorated and also the utility efficiency of the memory device 150 may decrease because characteristics are deteriorated in the memory blocks due to the performance of the command operations. Therefore, a copy operation or a swap operation may be performed in the memory device 150 in consideration of the parameters for the memory device 150 according to the performance of the command operations.

Herein, in the memory system in accordance with an embodiment of the present invention, when the controller 130 performs command operations corresponding to a plurality of commands in the memory blocks, the operation reliability of the memory device 150 may be deteriorated and read disturb or retention problems toward data stored in memory blocks of memory device 150 may occur because characteristics are deteriorated in the memory blocks due to the performance of the command operations and elapsing time after the performing command operations in memory blocks. Therefore, in the memory system in accordance with an embodiment of the present invention, the controller 130 may check parameters for the memory blocks of the memory device 150 and perform command operations and copy operation in the memory blocks of the memory device 150 according to the parameters for the memory blocks of the memory device 150.

In the memory system in accordance with an embodiment of the present invention, the controller 130 may perform foreground operation and background operation in the memory blocks of the memory device 150 according to the parameters for the memory blocks of the memory device 150.

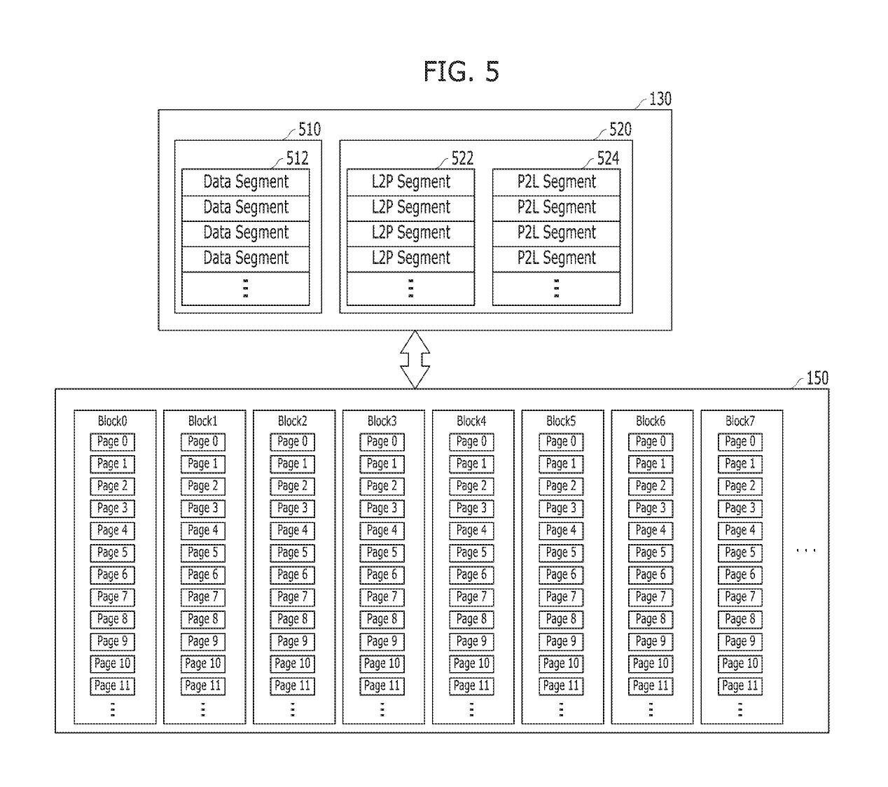

The performance of command operations corresponding to a plurality of commands and the performance of the command operations and the copy operations performed in the memory device 150 in consideration of the parameters corresponding to the performance of the command operations will be further described in detail later with references to FIGS. 5 to 8. Accordingly, further descriptions on those features are omitted here.

The processor 134 of the controller 130 may include a management unit (not illustrated) for performing a bad management operation of the memory device 150. The management unit may perform a bad block management operation of checking a bad block, in which a program fail occurs due to a characteristic of the memory device, for example, a NAND flash memory during a program operation, among the plurality of memory blocks 152 to 156. The management unit may write the program-failed data of the bad block to a new memory block. In a memory device 150 having a 3D stack structure, the bad block management operation may reduce the use efficiency of the memory device 150 and the reliability of the memory system 110. Thus, the bad block management operation needs to be performed with more reliability. The memory device of the memory system in accordance with an embodiment of the present invention is described in detail with reference to FIGS. 2 to 4.

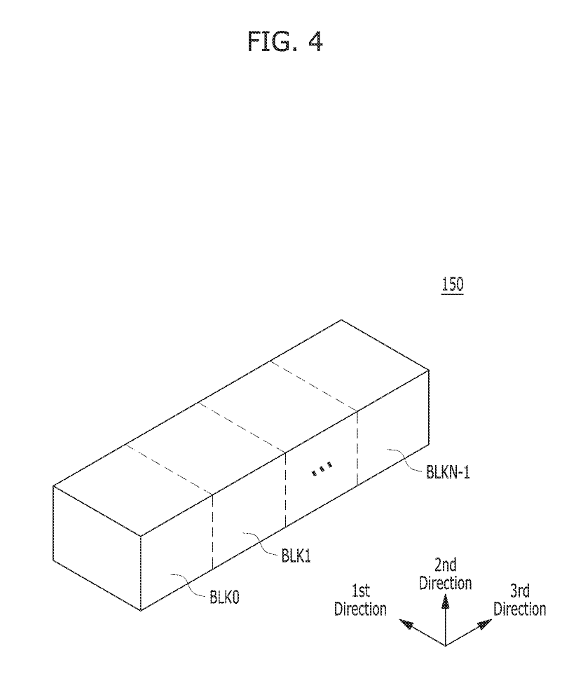

FIG. 2 is a schematic diagram illustrating the memory device 150, FIG. 3 is a circuit diagram illustrating an exemplary configuration of a memory cell array of a memory block in the memory device 150, and FIG. 4 is a schematic diagram illustrating an exemplary 3D structure of the memory device 150.

Referring to FIG. 2, the memory device 150 may include a plurality of memory blocks 0 to N-1, e.g., a memory block 0 (BLK0) 210, a memory block 1 (BLK1) 220, a memory block 2 (BLK2) 230, and a memory block N-1 (BLKN-1) 240, and each of the memory blocks 210, 220, 230 and 240 may include a plurality of pages, for example, 2^{M} pages, the number of which may vary according to circuit design. For example, instead of 2^{M} pages, each of the memory blocks may include M pages. Each of the pages may include a plurality of memory cells that are coupled to a plurality of word lines WL.

Also, the memory device 150 may include a plurality of memory blocks, which may include a single level cell (SLC) memory block storing 1-bit data and/or a multi-level cell (MLC) memory block storing 2-bit data. The SLC memory blocks may include a plurality of pages that are realized by memory cells storing one-bit data in one memory cell. The SLC memory blocks may have a quick data operation performance and high durability. On the other hand, the MLC memory blocks may include a plurality of pages that are realized by memory cells storing multi-bit data, e.g., data of two or more bits, in one memory cell. The MLC memory blocks may have a greater data storing space than the SLC memory blocks. In other words, the MLC memory blocks may be highly integrated. Particularly, the memory device 150 may include not only the MLC memory blocks each of which includes a plurality of pages that are realized by memory cells capable of storing two-bit data in one memory cell, but also triple level cell (TLC) memory blocks each of which includes a plurality of pages that are realized by memory cells capable of storing three-bit data in one memory cell, quadruple level cell (QLC) memory blocks each of which includes a plurality of pages that are realized by memory cells capable of storing four-bit data in one memory cell, and/or multiple level cell memory blocks each of which includes a plurality of pages that are realized by memory cells capable of storing five or more-bit data in one memory cell.

In accordance with an embodiment of the present invention, the memory device 150 is described as a non-volatile memory, such as a flash memory, e.g., a NAND flash memory. However, the memory device 150 may be realized as a Phase Change Random Access Memory (PCRAM), a Resistive Random Access Memory (RRAM or ReRAM), a Ferroelectric Random Access Memory (FRAM), and/or a Spin Transfer Torque Magnetic Random Access Memory (STT-RAM or STT-MRAM).

The memory blocks 210, 220, 230 and 240 may store the data provided from the host 102 through a program operation, and provide data stored therein to the host 102 through a read operation.

Referring to FIG. 3, a memory block 330 which may correspond to any of the plurality of memory blocks 152 to 156 of the memory system 110 may include a plurality of cell strings 340 coupled to a plurality of corresponding bit lines BL0 to BLm-1. The cell string 340 of each column may include one or more drain select transistors DST and one or more source select transistors SST. Between the drain and select transistors DST and SST, a plurality of memory cells MC0 to MCn-1 may be coupled in series. In an embodiment, each of the memory cell transistors MC0 to MCn-1 may be embodied by an MLC capable of storing data information of a plurality of bits. Each of the cell strings 340 may be electrically coupled to a corresponding bit line among the plurality of bit lines BL0 to BLm-1. For example, as illustrated in FIG. 3, the first cell string is coupled to the first bit line BL0, and the last cell string is coupled to the last bit line BLm-1.

Although FIG. 3 illustrates NAND flash memory cells, the invention is not limited in this way. It is noted that the memory cells may be NOR flash memory cells, or hybrid flash memory cells including two or more types of memory cells combined therein. Also, it is noted that the memory device 150 may be a flash memory device including a conductive floating gate as a charge storage layer or a charge trap flash (CTF) memory device including an insulation layer as a charge storage layer.

The memory device 150 may further include a voltage supply 310 which provides word line voltages including a program voltage, a read voltage and a pass voltage to supply to the word lines according to an operation mode. The voltage generation operation of the voltage supply 310 may be controlled by a control circuit (not illustrated). Under the control of the control circuit, the voltage supply 310 may select one of the memory blocks (or sectors) of the memory cell array, select one of the word lines of the selected memory block, and provide the word line voltages to the selected word line and the unselected word lines as may be needed.

The memory device 150 may include a read/write circuit 320 which is controlled by the control circuit. During a verification/normal read operation, the read/write circuit 320 may operate as a sense amplifier for reading data from the memory cell array. During a program operation, the read/write circuit 320 may operate as a write driver for driving bit lines according to data to be stored in the memory cell array. During a program operation, the read/write circuit 320 may receive from a buffer (not illustrated) data to be stored into the memory cell array, and drive bit lines according to the received data. The read/write circuit 320 may include a plurality of page buffers 322 to 326 respectively corresponding to columns (or bit lines) or column pairs (or bit line pairs), and each of the page buffers 322 to 326 may include a plurality of latches (not illustrated).

The memory device 150 may be embodied by a 2D or 3D memory device. Particularly, as illustrated in FIG. 4, the memory device 150 may be embodied by a nonvolatile memory device having a 3D stack structure. When the memory device 150 has a 3D structure, the memory device 150 may include a plurality of memory blocks BLK0 to BLKN-1. FIG. 4 is a block diagram illustrating the memory blocks 152 to 156 shown in FIG. 1. Each of the memory blocks 152 to 156 may be realized in a 3D structure (or vertical structure). For example, the memory blocks 152 to 156 may have a three-dimensional structure with dimensions extending in first to third directions, e.g., an x-axis direction, a y-axis direction, and a z-axis direction.

Each memory block 330 may include a plurality of NAND strings NS that extend in the second direction, and a plurality of NAND strings NS that extend in the first direction and the third direction. Each of the NAND strings NS may be coupled to a bit line BL, at least one string selection line SSL, at least one ground selection line GSL, a plurality of word lines WL, at least one dummy word line DWL, and a common source line CSL, and each of the NAND strings NS may include a plurality of transistor structures TS.

In short, each memory block 330 among the memory blocks 152 to 156 may be coupled to a plurality of bit lines BL, a plurality of string selection lines SSL, a plurality of ground selection lines GSL, a plurality of word lines WL, a plurality of dummy word lines DWL, and a plurality of common source lines CSL, and each memory block 330 may include a plurality of NAND strings NS. Also, in each memory block 330, one bit line BL may be coupled to a plurality of NAND strings NS to realize a plurality of transistors in one NAND string NS. Also, a string selection transistor SST of each NAND string NS may be coupled to a corresponding bit line BL, and a ground selection transistor GST of each NAND string NS may be coupled to a common source line CSL. Memory cells MC may be provided between the string selection transistor SST and the ground selection transistor GST of each NAND string NS. In other words, a plurality of memory cells may be realized in each memory block 330. A data processing operation toward a memory device, particularly, a data processing operation performed when a plurality of command operations corresponding to a plurality of commands are performed, in a memory system in accordance with an embodiment of the present invention is described in detail with reference to FIGS. 5 to 8.

FIGS. 5 to 7 illustrate an example of a data processing operation when a plurality of command operations corresponding to a plurality of commands are performed in a memory system in accordance with an embodiment of the present invention. By way of example, a case where a plurality of commands are received from the host 102 and command operations corresponding to the received commands are performed in the memory system 110 of FIG. 1 is described in detail. Such a case includes configurations in which a plurality of write commands are received from the host 102 and program operations corresponding to the write commands are performed, or a plurality of read commands are received from the host 102 and read operations corresponding to the read commands are performed, or a plurality of erase commands are received from the host 102 and erase operations corresponding to the erase commands are performed, or a plurality of write commands and a plurality of read commands are received together from the host 102 and program operations and read operations corresponding to the write commands and the read commands are performed.

Also, cases where write data corresponding to a plurality of write commands are stored in a buffer/cache included in the memory 144 of the controller 130, and then the data stored in the buffer/cache are programmed and stored in a plurality of memory blocks (in short, program operations are performed), and also where map data are updated corresponding to the program operations into the memory device 150 and then the updated map data are stored in the memory blocks may be taken as an example and described herein. In short, performing program operations corresponding to a plurality of write commands are performed is shown an example and described.

Also, a case when a plurality of read commands are received from the host 102 for the data stored in the memory device 150, the data corresponding to the read commands are read from the memory device 150 by detecting the map data for the data corresponding to the read commands and the read data are stored in the buffer/cache included in the memory 144 of the controller 130 and the data stored in the buffer/cache are provided to the host 102 may be taken as an example and described herein. In short, a case where read operations corresponding to the read commands are performed is shown as an example and described herein.

Also, a case where when a plurality of erase commands are received from the host 102 for the memory blocks, the memory blocks corresponding to the erase commands are detected and the data stored in the detected memory blocks are erased and the map data are updated corresponding to the erased data and the updated map data are stored in the memory blocks may be taken as an example and described herein. In short, a case where erase operations are performed is shown as an example and described.

It is assumed in an embodiment of the present invention for the sake of convenience that the command operations performed in the memory system 110 are performed by the controller 130. However, this is merely an example and, as described above, the processor 134 included in the controller 130, e.g., the FTL, may perform the command operations.

Also, in an embodiment of the present invention, the controller 130 may program and store the user data corresponding to the write commands and the metadata in some memory blocks among the memory blocks, read the user data corresponding to the read commands and the metadata from the memory blocks storing the user data and the metadata among the memory blocks and provide the read user data and the metadata to the host 102, or erase the user data and metadata from the memory blocks storing the user data and the metadata among the memory blocks.

The metadata may include first map data including Logical to Physical (L2P) information (hereinafter referred to as “logical information”) for the data stored in memory blocks through a program operation, and second map data including Physical to Logical (P2L) information (hereinafter referred to as “physical information”). Also, the metadata may include information on the command data corresponding to a command, information on a command operation corresponding to the command, information on the memory blocks where the command operation is performed, and information on the map data corresponding to the command operation. In other words, the metadata may include all the other information and data except the user data corresponding to a command.

According to an embodiment of the present invention, the controller 130 may perform command operations corresponding to a plurality of commands. For example, when the controller 130 receives write commands from the host 102, the controller 130 may perform program operations corresponding to the write commands. The controller 130 may write and store user data corresponding to the write commands in the memory blocks, such as empty memory blocks, open memory blocks, or free memory blocks where an erase operation is performed. Also, the controller 130 may write and store mapping information between the logical addresses and the physical addresses for the user data stored in the memory blocks (which are the first map data including an L2P map table or an L2P map list containing logical information) and mapping information between the physical addresses and the logical addresses for the memory blocks storing the user data (which are the second map data including a P2L map table or a P2L map list containing physical information) in the empty memory blocks, open memory blocks, or free memory blocks among the memory blocks.

When the controller 130 receives write commands from the host 102, the controller 130 may write and store user data corresponding to the write commands in the memory blocks, and store metadata that includes the first map data and the second map data for the user data stored in the memory blocks in memory blocks. Particularly, since data segments of the user data are stored in the memory blocks, the controller 130 may generate and update meta segments of the meta-data, which are map segments of map data including L2P segments of the first map data and P2L segments of the second map data, and store them in the memory blocks. Herein, the map segments stored in the memory blocks may be loaded onto the memory 144 of the controller 130 to be updated.

Also, when the controller 130 receives a plurality of read commands from the host 102, the controller 130 may read out the read data corresponding to the read commands from the memory device 150, store the read data in the buffer/cache included in the memory 144 of the controller 130, and provide the data stored in the buffer/cache to the host 102. In this manner, read operations corresponding to the read commands may be performed.

Also, when the controller 130 receives a plurality of erase commands from the host 102, the controller 130 may detect memory blocks that correspond to the erase commands and perform erase operations on the detected memory blocks. Hereafter, a data processing operation performed in the memory system in accordance with embodiments of the present invention is described in detail with reference to FIGS. 5 to 7.

Referring to FIG. 5, the controller 130 may perform command operations corresponding to a plurality of commands. For example, the controller 130 may perform program operations corresponding to a plurality of write commands. The controller 130 may program and store user data corresponding to the write commands in memory blocks, and generate and update metadata for the user data when the program operations are performed on the memory blocks, and then store the generated and updated metadata in the memory blocks.

The controller 130 may generate and update first map data and second map data that include information representing that the user data are stored in the pages in the memory blocks. In other words, the controller 130 may generate and update logical segments of the first map data, which include L2P segments, and physical segments of the second map data, which include P2L segments, and store the generated and updated logical segments in the pages included in the memory blocks.

For example, the controller 130 may cache and buffer the user data corresponding to the write commands in a first buffer 510 in the memory 144 of the controller 130. In other words, the controller 130 may store data segments 512 of the user data in the first buffer 510, which is a data buffer/cache, and store the data segments 512 stored in the first buffer 510 in the pages in the memory blocks. Since the data segments 512 of the user data corresponding to the write commands are programmed and stored in the pages in the memory blocks, the controller 130 may generate and update the first map data and the second map data and store them in a second buffer 520 in the memory 144 of the controller 130. Particularly, the controller 130 may store L2P segments 522 of the first map data and P2L segments 524 of the second map data for the user data in the second buffer 520, which is a map buffer/cache. As described above, the L2P segments 522 of the first map data and the P2L segments 524 of the second map data or a map list for the L2P segments 522 of the first map data and a map list for the P2L segments 524 of the second map data may be stored in the second buffer 520 in the memory 144 of the controller 130. Also, the controller 130 may store the L2P segments 522 of the first map data and the P2L segments 524 of the second map data that are stored in the second buffer 520 in the pages in the memory blocks.

Also, the controller 130 may perform command operations corresponding to a plurality of commands. For example, the controller 130 may perform read operations corresponding to a plurality of read commands received from the host 102. The controller 130 may load and detect the map segments of the map data for the user data corresponding to the read commands, e.g., the L2P segments 522 of the first map data and the P2L segments 524 of the second map data, onto the second buffer 520, read the user data stored in the pages of the corresponding memory blocks among the memory blocks, store the data segments 512 of the read user data in the first buffer 510, and provide them to the host 102.

In addition, the controller 130 may perform command operations corresponding to a plurality of commands. For example, the controller 130 may perform erase operations corresponding to a plurality of erase commands received from the host 102. The controller 130 may detect memory blocks corresponding to the erase commands among the memory blocks, and perform the erase operations on the detected memory blocks.

When a background operation, for example, an operation of copying data or swapping data from the memory blocks, such as a garbage collection operation or a wear-leveling operation, is performed, the controller 130 may store the data segments 512 of the corresponding user data in the first buffer 510, load the map segments 522 and 524 of the map data corresponding to the user data onto the second buffer 520, and perform the garbage collection operation or the wear-leveling operation.

As described above, when performing the command operations on the memory blocks, the controller 130 may detect parameters for the memory blocks, and perform the command operations and a copy operation on the memory blocks based on the parameters for the memory blocks. The controller 130 may check erase states of the memory blocks based on the parameters for the memory blocks. The controller 130 may perform the command operations or the copy operation on the memory blocks corresponding to the erase states. Particularly, the controller 130 may perform the erase operations on the memory blocks, and then check the erase states of the memory blocks where the erase operations are performed. Also, when performing the program operations corresponding to the write commands, the controller 130 may check the erase states of the memory blocks before performing the program operations. When a power state of the memory system 110 changes, that is, the memory system 110 changes from a power-on state to a power-off state due to sudden power-off occurring in the memory system 110, and then changes to the power-on state again, the controller 130 may check the erase states of the memory blocks. The controller 130 may perform the program operations or the copy operation on the memory blocks corresponding to the erase states of the memory blocks.

Referring to FIG. 6, the memory device 150 may include a plurality of memory dies, e.g., a memory die 0, a memory die 1, a memory die 2, and a memory die 3. Each of the memory dies may include a plurality of planes, e.g., a plane 0, a plane 1, a plane 2, and a plane 3. Each of the planes of the memory dies may include a plurality of memory blocks. For example, as described earlier with reference to FIG. 2, each of the planes may include N blocks BLK0, BLK1, . . . , BLKN-1, each including a plurality of pages, e.g., 2^{M} pages.

The memory device 150 may also include a plurality of buffers that respectively correspond to the memory dies. For example, the memory device 150 may include a buffer 0 corresponding to the memory die 0, a buffer 1 corresponding to the memory die 1, a buffer 2 corresponding to the memory die 2, and a buffer 3 corresponding to the memory die 3.

When the command operations corresponding to the plurality of commands are performed, data corresponding to the command operations may be stored in the buffers included in the memory device 150. For example, when the program operations are performed, data corresponding to the program operations may be stored in the buffers, and then stored in the pages in the memory blocks of the memory dies. When read operations are performed, data corresponding to the read operations may be read from the pages included in the memory blocks of the memory dies, stored in the buffers, and provided to the host 102 through the controller 130.

In an embodiment of the present invention, for the sake of convenience, a case where the buffers exist outside of the corresponding memory dies is provided as an example and described. However, the buffers may exist inside of the corresponding memory dies. Also, the buffers may correspond to the planes or the memory blocks in the memory dies. By way of example, a case where the buffers are a plurality of page buffers 322, 324 and 326 is provided as an example, as described earlier with reference to FIG. 3. However, the buffers may be a plurality of caches or a plurality of registers.

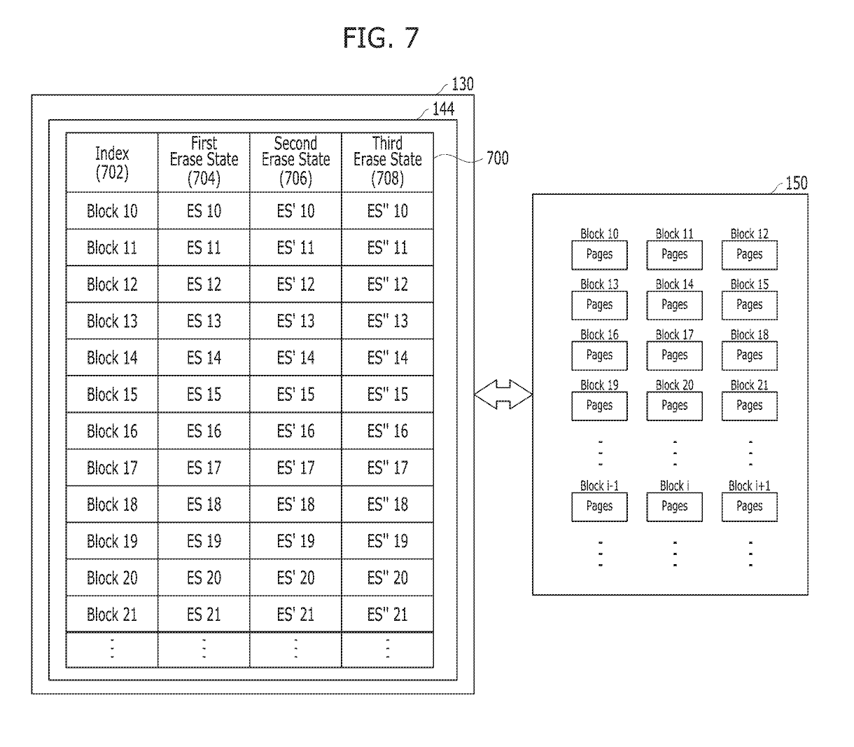

Also, the memory blocks may be grouped into a plurality of super memory blocks, and then the command operations may be performed on the super memory blocks. Each of the super memory blocks may include a plurality of memory blocks, for example, memory blocks included in a first memory block group and a second memory block group. When the first memory block group is included in a first plane of a first memory die, the second memory block group may be included in the first plane of the first memory die, a second plane of the first memory die, or planes of a second memory die. As described earlier, when the command operations corresponding to the commands are performed on the memory blocks, the parameters for each memory block corresponding to the performance of the command operations may be detected, and then the command operations and the copy operation may be performed on the memory blocks based on the parameters. Detailed descriptions of these aspects are provided with reference to FIG. 7.

Referring to FIG. 7, when the controller 130 receives a is plurality of erase commands from the host 102, the controller 130 may control the memory device 150 to perform corresponding erase operations on a plurality of memory blocks. The controller 130 may detect parameters for the memory blocks. Particularly, the controller 130 may check erase states of the memory blocks where the erase operations are performed. In addition, when the controller 130 receives a plurality of write commands from the host 102, the controller 130 may check the erase states of the memory blocks before performing the program operations corresponding to the write commands. When a power state of the memory system 110 changes, that is, the memory system 110 changes from a power-on state to a power-off state due to sudden power-off occurring in the memory system 110, and then changes to the power-on state again, the controller 130 may check the erase states of the memory blocks.

The controller 130 may check an erase state of a monitoring zone in each of the memory blocks. The monitoring zone may be set among a plurality of word lines or a plurality of pages in each of the memory blocks. In other words, the monitoring zone may be a word line among the word lines in each of the memory blocks or a monitoring page among the pages included in each of the memory blocks.

The monitoring zone may be set as a last word line among the word lines in each of the memory blocks, or as the last page among the pages in each of the memory blocks. When data are to be stored is in each of the memory blocks, the last word line and the last page may be considered as a last location where the data are to be stored for each memory block.

The controller 130 may check an erase state of the last word line or the last page (i.e., the monitoring zone) in each of the memory blocks, thereby checking the erase states of the memory blocks. The controller 130 may check erase voltage distribution or erase voltage offset distribution of the last word line or the last page for each memory block, check the erase state of the last word line or the last page in each of the memory blocks through the erase voltage distribution or the erase voltage offset distribution, and check the erase states of the memory blocks.

The controller 130 may control the memory device 150 to perform a read operation to the last word line or the last page by changing a read voltage in each memory block, thereby checking the erase voltage distribution or the erase voltage offset distribution of the last word line or the last page in each memory block.

The controller 130 may provide erase check commands to the memory device 150 for checking the erase states of the respective memory blocks, thereby checking the erase voltage distribution or the erase voltage offset distribution of the last word line or the last page. The erase check commands may be provided from the controller 130 to the memory device 150 after being generated from the controller 130 or provided from the host 102 to the memory device 150 through the controller 130 after being generated from the host 102.

For example, when the erase voltage distribution or the erase voltage offset distribution of the last word line or the last page of first source memory blocks among the memory blocks exceeds a threshold value, the controller 130 may determine that the erase state of the first source memory blocks is in a bad state or an abnormal state.

The controller 130 may copy data from the first source memory blocks in the bad state or the abnormal state into target memory blocks, and then process the first source memory blocks in the bad state or the abnormal state as dosed memory blocks. The target memory blocks may be empty memory blocks, open memory blocks or free memory blocks among the memory blocks of the memory device 150.

When the erase voltage distribution or the erase voltage offset distribution of the last word line or the last page of second source memory blocks among the memory blocks is below the threshold value, the controller 130 may determine that the erase state of the second source memory blocks is in a normal state. The controller 130 may perform command operations on the second source memory blocks in the normal state. Particularly, the controller 130 may store data in empty pages, open pages or free pages where the erase operation is performed among the second source memory blocks.

In other words, the controller 130 may check the erase states of the memory blocks through the monitoring zone of each of the memory blocks, and subsequently control the memory device 150 to perform the background operation on the memory blocks in the bad state or the abnormal state and perform the command operations, particularly, the program operations, as the foreground operation on the memory blocks in the normal state.

More specifically, the controller 130 may perform the erase operations on the memory blocks, for example, a memory block 10, a memory block 11, a memory block 12, a memory block 13, a memory block 14, a memory block 15, a memory block 16, a memory block 17, a memory block 18, a memory block 19, a memory block 20 and a memory block 21.

The controller 130 may check the erase states of the memory blocks based on performance of the erase operations. Particularly, the controller 130 may check the erase voltage distribution or the erase voltage offset distribution of the last word line or the last page as the monitoring zone of each of the memory blocks where the erase operations are performed, and check the erase states of the memory blocks through the erase voltage distribution or the erase voltage offset distribution. The controller 130, as described above, may check the erase voltage distribution or the erase voltage offset distribution of the last word line or the last page as the monitoring zone of each of the memory blocks in response to the erase check commands or through the read operation to the monitoring zone of each of the memory blocks by changing the read voltage.

The controller 130 may record the erase states of the memory blocks in a state table 700 for each of the memory blocks in the index 702. The controller 130 may perform the erase operations on the memory blocks, and subsequently check the erase states of the memory blocks where the erase operations are performed and record the erase states of the memory blocks after the erase operations are performed as first erase states 704 in the state table 700. The erase voltage distribution or the erase voltage offset distribution of the monitoring zone in each of the memory blocks may be recorded as the first erase states 704 in the state table 700. The first erase states 704 recorded in the state table 700 for each of the memory blocks may represent initial erase states immediately after the erase operations are performed to the memory blocks.

The controller 130 may store the state table 700 where the first erase states 704 are recorded in the memory 144 of the controller 130 and store the state table 700 in meta-data in the memory device 150. Particularly, the controller 130 may include the first erase states 704 in checkpoint information and store the checkpoint information including the erase states 704 in the memory blocks. In short, the erase states of the memory blocks may be stored in the memory blocks as the checkpoint information.

When the controller 130 receives write commands from the host 102, the controller 130 may check the erase states of the memory blocks before performing the program operations on the memory blocks, for example, a memory block 10, a memory block 11, a memory block 12, a memory block 13, a memory block 14, a memory block 15, a memory block 16, a memory block 17, a memory block 18, a memory block 19, a memory block 20 and a memory block 21.

Particularly, the controller 130 may check the erase voltage distribution or the erase voltage offset distribution of the last word line or the last page as the monitoring zone of each of the memory blocks where the program operations are performed, and check the erase states of the memory blocks through the erase voltage distribution or the erase voltage offset distribution.

The controller 130, as described above, may check the erase voltage distribution or the erase voltage offset distribution of the last word line or the last page as the monitoring zone of each of the memory blocks in response to the erase check commands or through the read operation to the monitoring zone of each of the memory blocks by changing the read voltage.

In addition, when the controller 130 performs the read operations in response to read commands, the controller 130 may check the erase voltage distribution or the erase voltage offset distribution of the last word line or the last page as the monitoring zone of each of the memory blocks before performing the read operations.

The controller 130 may record the erase states of the respective memory blocks in the state table 700. Before performing the program operations on the memory blocks, the controller 130 may check the erase states of the memory blocks where the program operations are performed and record the erase states of the memory blocks before the program operations are performed as second erase states 706 in the state table 700. The erase voltage distribution or the erase voltage offset distribution of the monitoring zone in each of the memory blocks may be recorded as the second erase states 706 in the state table 700 for each of the memory blocks. The second erase states 706 recorded in the state table 700 may represent operation erase states before the program operations are performed to the memory blocks.

The controller 130 may check the erase states of the memory blocks before the read operations are performed on the memory blocks, and subsequently record the erase states of the memory blocks before the read operations are performed as the second erase states 706 in the state table 700. The second erase states 706 recorded in the state table 700 may represent operation erase states before the read operations are performed to the memory blocks.

The controller 130 may store the state table 700 where the second erase states 706 are recorded in the memory 144 of the controller 130 and store the state table 700 in the memory device 150 in the form of meta-data. Particularly, the controller 130 may include the second erase states 706 in checkpoint information and store the checkpoint information in the second erase states 706 in the memory blocks. In short, the erase states of the memory blocks may be stored in the memory blocks as the checkpoint information.

When a power state of the memory system 110 changes, that is, the memory system 110 changes from a power-on state to a power-off state due to sudden power-off occurring in the memory system 110, and then changes to the power-on state again, the controller 130 may check the erase states of the memory blocks. The controller 130 may check the erase voltage distribution or the erase voltage offset distribution of the last word line or the last page as the monitoring zone of each of the memory blocks after the memory system 110 changes from the power-off state to the power-on state, and check the erase states of the memory blocks through the erase voltage distribution or the erase voltage offset distribution of the last word line or the last page as the monitoring zone of each of the memory blocks. The controller 130, as described above, may check the erase voltage distribution or the erase voltage offset distribution of the last word line or the last page as the monitoring zone of each of the memory blocks in response to the erase check commands or through the read operation to the monitoring zone of each of the memory blocks by changing the read voltage.

The controller 130 may record the erase states of the memory blocks in the state table 700 for each of the memory blocks. After the memory system 110 changes from the power-off state to the power-on state, the controller 130 may check the erase states of the memory blocks which changes from the power-off state to the power-on state, and record the erase states of the memory blocks after the power state changes as third erase states 708 in the state table 700. The erase voltage distribution or the erase voltage offset distribution of the monitoring zone in each of the memory blocks may be recorded as the third erase states 706 in the state table 700. The third erase states 708 recorded in the state table 700 for each of the memory blocks may represent erase states immediately after the power state changes among the memory blocks.

The controller 130 may store the state table 700 where the third erase states 708 are recorded in the memory 144 of the controller 130 and store the state table 700 in the memory device 150 as meta-data. Particularly, the controller 130 may include the third erase states 708 in checkpoint information and store such checkpoint information in the memory blocks. In short, the erase states of the memory blocks may be stored in the memory blocks as the checkpoint information.

Particularly, the controller 130 may check the erase voltage distribution or the erase voltage offset distribution of the last word line or the last page as the monitoring zone of each of the memory blocks, check the erase states of the memory blocks through the erase voltage distribution or the erase voltage offset distribution, record the erase states of the memory blocks in the state table 700, and perform the foreground operation and the background operation on the memory blocks according to the erase states of the memory blocks recorded in the state table 700.

For the sake of convenience, a case where the erase voltage distribution or the erase voltage offset distribution of the monitoring zone of each of the memory block 11, the memory block 15 and the memory block 19 exceeds the threshold value is described in detail as an example.

The controller 130 may check the erase states of the memory blocks recorded in the state table 700. Particularly, the controller 130 may check that the erase voltage distribution or the erase voltage offset distribution of the last word line or the last page as the monitoring zone of each of the memory block 11, the memory block 15 and the memory block 19 exceeds the threshold value, thereby determining the memory block 11, the memory block 15 and the memory block 19 to be in the bad or abnormal states.

The controller 130 may control the memory device 150 to perform the background operation on the memory block 11, the memory block 15 and the memory block 19, which are in the bad or abnormal states.

The controller 130 may copy data from the memory block 11, the memory block 15 and the memory block 19 into new empty memory blocks, open memory blocks or free memory blocks among the memory blocks, for example, a memory block i−1, a memory block i and a memory block i+1. The controller 130 may process the memory block 11, the memory block 15 and the memory block 19 as closed memory blocks.

In other words, the controller 130 may control the memory device 150 not to perform the program operations on the memory block 11, the memory block 15 and the memory block 19 even though the empty pages, the open pages or the free pages exist in the memory block 11, the memory block 15 and the memory block 19. Accordingly, data may not be stored in the empty pages, the open pages or the free pages included in the memory block 11, the memory block 15 and the memory block 19. When the controller 130 receives the write commands for the memory block 11, the memory block 15 and the memory block 19, the controller 130 may process the memory block 11, the memory block 15 and the memory block 19 as closed memory blocks and control the memory device 150 to perform the program operations on the memory block i−1, the memory block i and the memory block i+1 which are assigned as new memory blocks.

Also, the controller 130 may check the erase states of the memory blocks recorded in the state table 700. Particularly, the controller 130 may check that the erase voltage distribution or the erase voltage offset distribution of the last word line or the last page as the monitoring zone of the memory block 10, the memory block 12, the memory block 13, the memory block 14, the memory block 16, the memory block 17, the memory block 18, the memory block 20 and the memory block 21 is below the threshold value, thereby determining the memory block 10, the memory block 12, the memory block 13, the memory block 14, the memory block 16, the memory block 17, the memory block 18, the memory block 20 and the memory block 21 to be in the normal states.

The controller 130 may control the memory device 150 to perform the foreground operation on the memory block 10, the memory block 12, the memory block 13, the memory block 14, the memory block 16, the memory block 17, the memory block 18, the memory block 20 and the memory block 21, which are in the normal states.

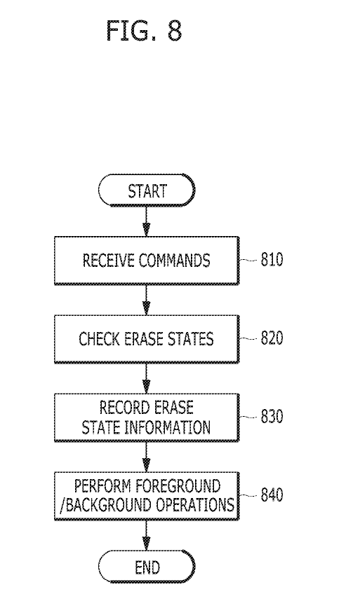

The controller 130 may control the memory device 150 to perform the program operations corresponding to the write commands on the memory block 10, the memory block 12, the memory block 13, the memory block 14, the memory block 16, the memory block 17, the memory block 18, the memory block 20 and the memory block 21, and control the memory device 150 to perform the read operations corresponding to the read commands on the memory block 10, the memory block 12, the memory block 13, the memory block 14, the memory block 16, the memory block 17, the memory block 18, the memory block 20 and the memory block 21. The controller 130 may control the memory device 150 to store data corresponding to the write commands in empty memory blocks, open memory blocks or free memory blocks included in the memory block 10, the memory block 12, the memory block 13, the memory block 14, the memory block 16, the memory block 17, the memory block 18, the memory block 20 and the memory block 21. An operation of processing data in the memory system in accordance with an embodiment of the present invention is described in detail below with reference to FIG. 8.

FIG. 8 is a flowchart describing an operation process of processing data in the memory system in accordance with an embodiment of the present invention.

Referring to FIG. 8, the memory system 110 may receive a plurality of commands, for example, a plurality of write commands, a plurality of read commands, and/or a plurality of erase commands, from the host 102, at step S810.

At step S820, the memory system 110 may check erase states of the memory blocks of the memory device 150. For example, the memory system 110 may perform erase operations corresponding to the erase commands received from the host 102 on the memory blocks, and check the erase states of the memory blocks after the erase operations are performed. Particularly, the memory system 110 may check the erase state of a last word line or a last page as a monitoring zone of each of the memory blocks. The memory system 110 may check erase voltage distribution or erase voltage offset distribution of the last word line or the last page of each of the memory blocks, thereby checking the erase states of the memory blocks after the erase operations are performed.

Also, before performing program operations corresponding to write commands or performing read operations corresponding to read commands, the memory system 110 may check the erase states of the memory blocks. The memory system 110 may check erase voltage distribution or erase voltage offset distribution of a last word line or a last page of each of the memory blocks where the program or read operations are to be performed, thereby checking the erase states of the memory blocks before the program or read operations are performed.

When a power state of the memory system 110 changes, that is, the memory system 110 changes from a power-on state to a power-off state due to sudden power-off occurring in the memory system 110, and then changes to the power-on state again, the memory system 110 may check the erase states of the memory blocks. The memory system 110 may check the erase voltage distribution or the erase voltage offset distribution of the last word line or the last page of each of the memory blocks whose power state changes, thereby checking the erase states of the memory blocks after the power state changes.

At step S830, the memory system 110 may record the erase state of each of the memory blocks in a state table.

At step S840, the memory system 110 may perform a background operation and a foreground operation on the memory blocks corresponding to the erase states of the memory blocks recorded in the state table. The memory system 110 may perform a copy operation on the memory blocks in bad or abnormal states among the memory blocks, and perform command operations, particularly, the program operations on the memory blocks in normal states.

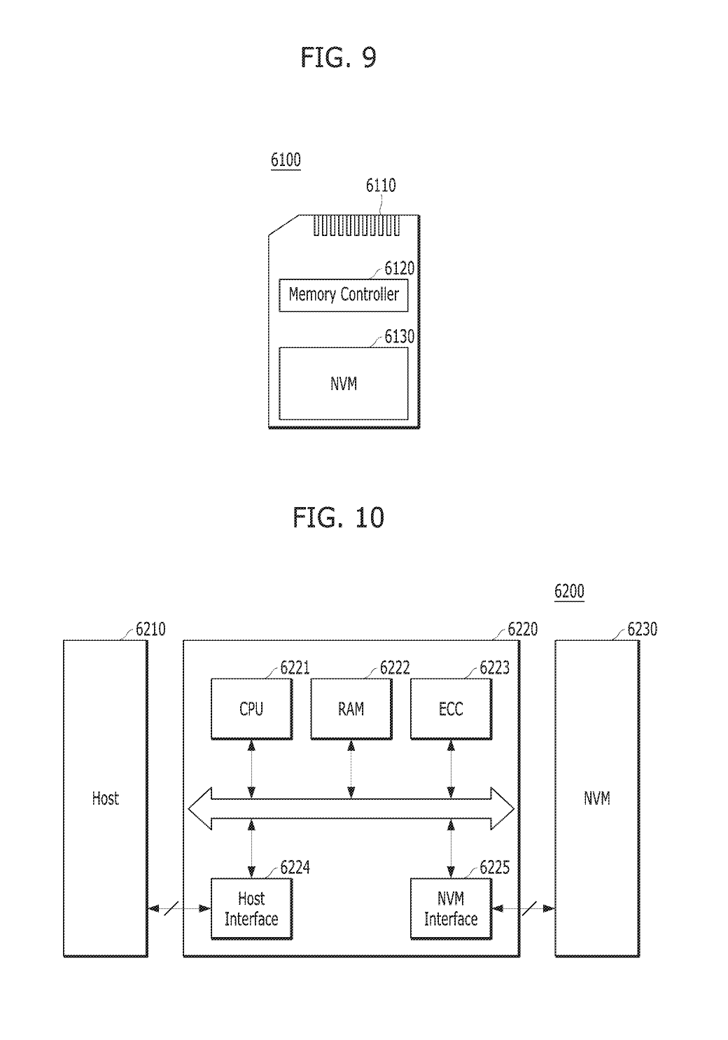

Since checking the erase states of the memory blocks and performing the background operation and the foreground operation on the memory blocks corresponding to the erase states are described above in detail with reference to FIGS. 5 to 7, further description thereon is omitted here. A data processing system and electronic devices to which the memory system 110 including the memory device 150 and the controller 130, which are described above by referring to FIGS. 1 to 8, in accordance with an embodiment of the present invention will be described in detail with reference to FIGS. 9 to 17.

FIG. 9 is a diagram schematically illustrating another example of the data processing system including the memory system in accordance with an embodiment. FIG. 9 schematically illustrates a memory card system to which the memory system may be applied.

Referring to FIG. 9, the memory card system 6100 may include a memory controller 6120, a memory device 6130 and a connector 6110.

More specifically, the memory controller 6120 may be connected to the memory device 6130 embodied by a nonvolatile memory, and configured to access the memory device 6130. For example, the memory controller 6120 may control read, write, erase and background operations of the memory device 6130. The memory controller 6120 may provide an interface between the memory device 6130 and a host, and drive firmware for controlling the memory device 6130. That is, the memory controller 6120 may correspond to the controller 130 of the memory system 110 described with reference to FIG. 1, and the memory device 6130 may correspond to the memory device 150 of the memory system 110 described with reference to FIG. 1.

Thus, the memory controller 6120 may include a RAM, a processor, a host interface, a memory interface and an error correction component.

The memory controller 6120 may communicate with an external device, for example, the host 102 of FIG. 1 through the connector 6110. For example, as described with reference to FIG. 1, the memory controller 6120 may communicate with an external device through one or more of various communication protocols such as universal serial bus (USB), multimedia card (MMC), embedded MMC (eMMC), peripheral component interconnection (PCI), PCI express (PCIe), Advanced Technology Attachment (ATA), Serial-ATA, Parallel-ATA, small computer system interface (SCSI), enhanced small disk interface (EDSI), Integrated Drive Electronics (IDE), Firewire, universal flash storage (UFS), WIFI and Bluetooth. Thus, the memory system and the data processing system in accordance with an embodiment may be applied to wired/wireless electronic devices, particularly mobile electronic devices.

The memory device 6130 may be implemented by a nonvolatile memory. For example, the memory device 6130 may be implemented by various nonvolatile memory devices such as an erasable and programmable ROM (EPROM), an electrically erasable and programmable ROM (EEPROM), a NAND flash memory, a NOR flash memory, a phase-change RAM (PRAM), a resistive RAM (ReRAM), a ferroelectric RAM (FRAM) and/or a spin torque transfer magnetic RAM (STT-RAM).

The memory controller 6120 and the memory device 6130 may be integrated into a single semiconductor device. For example, the memory controller 6120 and the memory device 6130 may be so integrated to form a solid-state driver (SSD). Also, the memory controller 6120 and the memory device 6130 may form a memory card such as a PC card (PCMCIA: Personal Computer Memory Card International Association), a compact flash (CF) card, a smart media card (e.g., SM and SMC), a memory stick, a multimedia card (e.g., MMC, RS-MMC, MMCmicro and eMMC), an SD card (e.g., SD, miniSD, microSD and SDHC) and/or a universal flash storage (UFS).

FIG. 10 is a diagram schematically illustrating another example of the data processing system including the memory system in accordance with an embodiment.

Referring to FIG. 10, the data processing system 6200 may include a memory device 6230 having one or more nonvolatile memories and a memory controller 6220 for controlling the memory device 6230. The data processing system 6200 illustrated in FIG. 10 may serve as a storage medium such as a memory card (CF, SD, micro-SD or the like) or USB device, as described with reference to FIG. 1. The memory device 6230 may correspond to the memory device 150 in the memory system 110 illustrated in FIG. 1, and the memory controller 6220 may correspond to the controller 130 in the memory system 110 illustrated in FIG. 1.

The memory controller 6220 may control a read, write or erase operation on the memory device 6230 in response to a request of the host 6210, and the memory controller 6220 may include one or more CPUs 6221, a buffer memory such as RAM 6222, an ECC circuit 6223, a host interface 6224 and a memory interface such as an NVM interface 6225.

The CPU 6221 may control overall operations on the memory device 6230, for example, read, write, file system management and bad page management operations. The RAM 6222 may be operated according to control of the CPU 6221, and used as a work memory, buffer memory or cache memory. When the RAM 6222 is used as a work memory, data processed by the CPU 6221 may be temporarily stored in the RAM 6222. When the RAM 6222 is used as a buffer memory, the RAM 6222 may be used for buffering data transmitted to the memory device 6230 from the host 6210 or transmitted to the host 6210 from the memory device 6230. When the RAM 6222 is used as a cache memory, the RAM 6222 may assist the low-speed memory device 6230 to operate at high speed.

The ECC circuit 6223 may correspond to the ECC component 138 of the controller 130 illustrated in FIG. 1. As described with reference to FIG. 1, the ECC circuit 6223 may generate an ECC (Error Correction Code) for correcting a fail bit or error bit of data provided from the memory device 6230. The ECC circuit 6223 may perform error correction encoding on data provided to the memory device 6230, thereby forming data with a parity bit. The parity bit may be stored in the memory device 6230. The ECC circuit 6223 may perform error correction decoding on data outputted from the memory device 6230. The ECC circuit 6223 may correct an error using the parity bit. For example, as described with reference to FIG. 1, the ECC circuit 6223 may correct an error using the LDPC code, BCH code, turbo code, Reed-Solomon code, convolution code, RSC or coded modulation such as TCM or BCM.

The memory controller 6220 may transmit/receive data to/from the host 6210 through the host interface 6224, and transmit/receive data to/from the memory device 6230 through the NVM interface 6225. The host interface 6224 may be connected to the host 6210 through a PATA bus, SATA bus, SCSI, USB, PCIe or NAND interface. The memory controller 6220 may have a wireless communication function with a mobile communication protocol such as WiFi or Long Term Evolution (LTE). The memory controller 6220 may be connected to an external device, for example, the host 6210 or another external device, and then transmit/receive data to/from the external device. In particular, as the memory controller 6220 is configured to communicate with the external device through one or more of various communication protocols, the memory system and the data processing system in accordance with an embodiment may be applied to wired/wireless electronic devices, particularly a mobile electronic device.

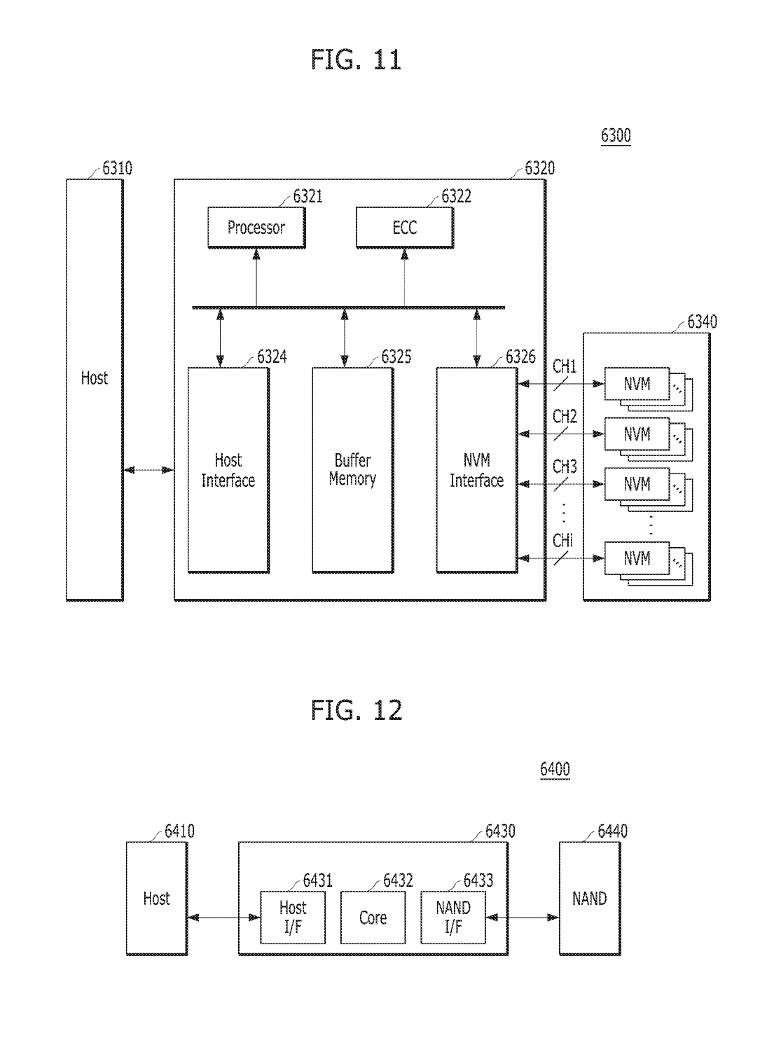

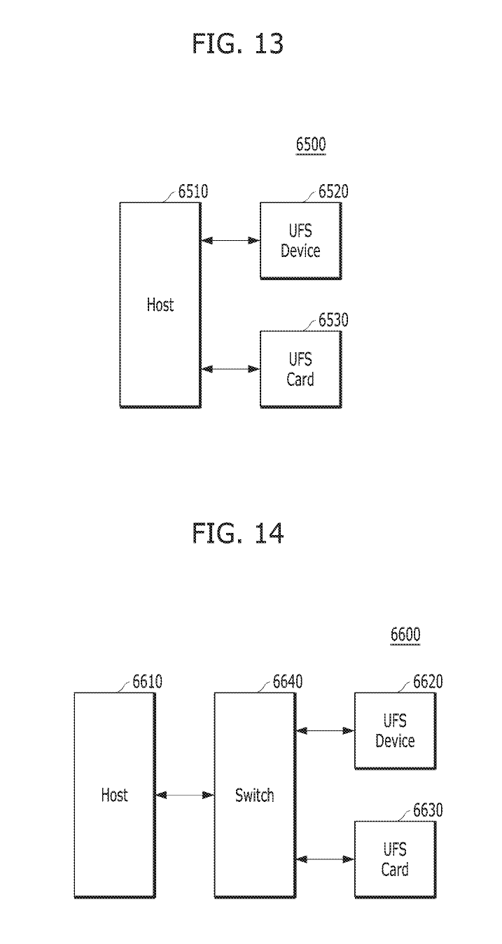

FIG. 11 is a diagram schematically illustrating another example of the data processing system including the memory system in accordance with an embodiment. FIG. 13 schematically illustrates an SSD to which the memory system may be applied.

Referring to FIG. 11, the SSD 6300 may include a controller 6320 and a memory device 6340 including a plurality of nonvolatile memories. The controller 6320 may correspond to the controller 130 in the memory system 110 of FIG. 1, and the memory device 6340 may correspond to the memory device 150 in the memory system of FIG. 1

More specifically, the controller 6320 may be connected to the memory device 6340 through a plurality of channels CH1 to CHi. The controller 6320 may include one or more processors 6321, a buffer memory 6325, an ECC circuit 6322, a host interface 6324 and a memory interface, for example, a nonvolatile memory interface 6326.

The buffer memory 6325 may temporarily store data provided from the host 6310 or data provided from a plurality of flash memories NVM included in the memory device 6340, or temporarily store meta-data of the plurality of flash memories NVM, for example, map data including a mapping table. The buffer memory 6325 may be embodied by volatile memories such as DRAM, SDRAM, DDR SDRAM, LPDDR SDRAM and GRAM or nonvolatile memories such as FRAM, ReRAM, STT-MRAM and PRAM. For convenience of description, FIG. 8 illustrates that the buffer memory 6325 exists in the controller 6320. However, the buffer memory 6325 may exist outside the controller 6320.

The ECC circuit 6322 may calculate an ECC value of data to be programmed to the memory device 6340 during a program operation, perform an error correction operation on data read from the memory device 6340 based on the ECC value during a read operation, and perform an error correction operation on data recovered from the memory device 6340 during a failed data recovery operation.

The host interface 6324 may provide an interface function with an external device, for example, the host 6310, and the nonvolatile memory interface 6326 may provide an interface function with the memory device 6340 connected through the plurality of channels.

Furthermore, a plurality of SSDs 6300 to which the memory system 110 of FIG. 1 is applied may be provided to embody a data processing system, for example, RAID (Redundant Array of Independent Disks) system. The RAID system may include the plurality of SSDs 6300 and a RAID controller for controlling the plurality of SSDs 6300. When the RAID controller performs a program operation in response to a write command provided from the host 6310, the RAID controller may select one or more memory systems or SSDs 6300 according to a plurality of RAID levels, that is, RAID level information of the write command provided from the host 6310 in the SSDs 6300, and output data corresponding to the write command to the selected SSDs 6300. Furthermore, when the RAID controller performs a read command in response to a read command provided from the host 6310, the RAID controller may select one or more memory systems or SSDs 6300 according to a plurality of RAID levels, that is, RAID level information of the read command provided from the host 6310 in the SSDs 6300, and provide data read from the selected SSDs 6300 to the host 6310.

FIG. 12 is a diagram schematically illustrating another example of the data processing system including the memory system in accordance with an embodiment. FIG. 12 schematically illustrates an embedded Multi-Media Card (eMMC) to which the memory system may be applied.

Referring to FIG. 12, the eMMC 6400 may include a controller 6430 and a memory device 6440 embodied by one or more NAND flash memories. The controller 6430 may correspond to the controller 130 in the memory system 110 of FIG. 1, and the memory device 6440 may correspond to the memory device 150 in the memory system 110 of FIG. 1.

More specifically, the controller 6430 may be connected to the memory device 6440 through a plurality of channels. The controller 6430 may include one or more cores 6432, a host interface 6431 and a memory interface, for example, a NAND interface 6433.

The core 6432 may control overall operations of the eMMC 6400, the host interface 6431 may provide an interface function between the controller 6430 and the host 6410, and the NAND interface 6433 may provide an interface function between the memory device 6440 and the controller 6430. For example, the host interface 6431 may serve as a parallel interface, for example, MMC interface as described with reference to FIG. 1. Furthermore, the host interface 6431 may serve as a serial interface, for example, UHS ((Ultra High Speed)-I/UHS-II) interface.

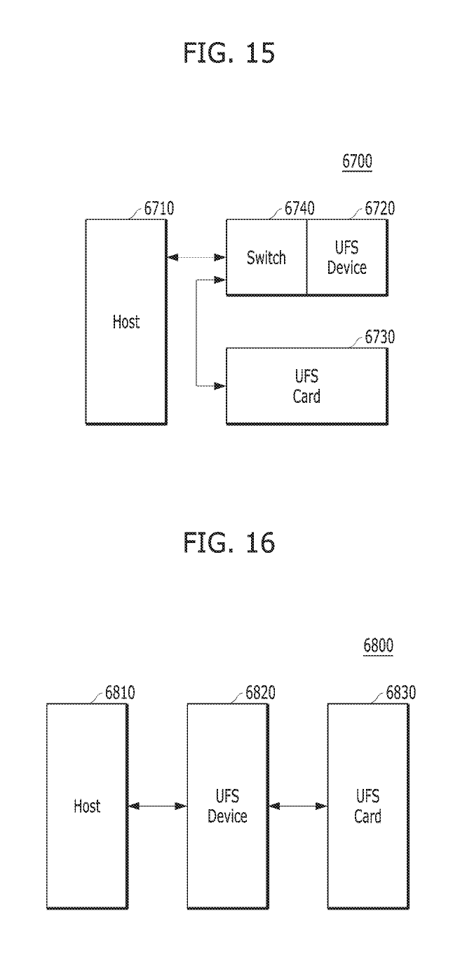

FIGS. 13 to 16 are diagrams schematically illustrating other examples of the data processing system including the memory system in accordance with one or more embodiments. FIGS. 15 to 18 schematically illustrate UFS (Universal Flash Storage) systems to which the memory system may be applied.

Referring to FIGS. 13 to 16, the UFS systems 6500, 6600, 6700 and 6800 may include hosts 6510, 6610, 6710 and 6810, UFS devices 6520, 6620, 6720 and 6820 and UFS cards 6530, 6630, 6730 and 6830, respectively. The hosts 6510, 6610, 6710 and 6810 may serve as application processors of wired/wireless electronic devices or particularly mobile electronic devices, the UFS devices 6520, 6620, 6720 and 6820 may serve as embedded UFS devices, and the UFS cards 6530, 6630, 6730 and 6830 may serve as external embedded UFS devices or removable UFS cards.

The hosts 6510, 6610, 6710 and 6810, the UFS devices 6520, 6620, 6720 and 6820 and the UFS cards 6530, 6630, 6730 and 6830 in the respective UFS systems 6500, 6600, 6700 and 6800 may communicate with external devices, for example, wired/wireless electronic devices or particularly mobile electronic devices through UFS protocols, and the UFS devices 6520, 6620, 6720 and 6820 and the UFS cards 6530, 6630, 6730 and 6830 may be embodied by the memory system 110 illustrated in FIG. 1. For example, in the UFS systems 6500, 6600, 6700 and 6800, the UFS devices 6520, 6620, 6720 and 6820 may be embodied in the form of the data processing system 6200, the SSD 6300 or the eMMC 6400 described with reference to FIGS. 12 to 14, and the UFS cards 6530, 6630, 6730 and 6830 may be embodied in the form of the memory card system 6100 described with reference to FIG. 9.

Furthermore, in the UFS systems 6500, 6600, 6700 and 6800, the hosts 6510, 6610, 6710 and 6810, the UFS devices 6520, 6620, 6720 and 6820 and the UFS cards 6530, 6630, 6730 and 6830 may communicate with each other through an UFS interface, for example, MIPI M-PHY and MIPI UniPro (Unified Protocol) in MIPI (Mobile Industry Processor Interface). Furthermore, the UFS devices 6520, 6620, 6720 and 6820 and the UFS cards 6530, 6630, 6730 and 6830 may communicate with each other through various protocols other than the UFS protocol, for example, UFDs, MMC, SD, mini-SD, and micro-SD.

In the UFS system 6500 illustrated in FIG. 13, each of the host 6510, the UFS device 6520 and the UFS card 6530 may include UniPro. The host 6510 may perform a switching operation in order to communicate with the UFS device 6520 and the UFS card 6530. In particular, the host 6510 may communicate with the UFS device 6520 or the UFS card 6530 through link layer switching, for example, L3 switching at the UniPro. The UFS device 6520 and the UFS card 6530 may communicate with each other through link layer switching at the UniPro of the host 6510. A configuration in which one UFS device 6520 and one UFS card 6530 are connected to the host 6510 is provided by way of example for convenience of description. However, a plurality of UFS devices and UFS cards may be connected in parallel or in the form of a star to the host 6410, and a plurality of UFS cards may be connected in parallel or in the form of a star to the UFS device 6520 or connected in series or in the form of a chain to the UFS device 6520.

In the UFS system 6600 illustrated in FIG. 14, each of the host 6610, the UFS device 6620 and the UFS card 6630 may include UniPro, and the host 6610 may communicate with the UFS device 6620 or the UFS card 6630 through a switching module 6640 performing a switching operation, for example, through the switching module 6640 which performs link layer switching at the UniPro, for example, L3 switching. The UFS device 6620 and the UFS card 6630 may communicate with each other through link layer switching of the switching module 6640 at UniPro. A configuration in which one UFS device 6620 and one UFS card 6630 are connected to the switching module 6640 is provided by way of example for convenience of description. However, a plurality of UFS devices and UFS cards may be connected in parallel or in the form of a star to the switching module 6640, and a plurality of UFS cards may be connected in series or in the form of a chain to the UFS device 6620.

In the UFS system 6700 illustrated in FIG. 15, each of the host 6710, the UFS device 6720 and the UFS card 6730 may include UniPro, and the host 6710 may communicate with the UFS device 6720 or the UFS card 6730 through a switching module 6740 performing a switching operation, for example, through the switching module 6740 which performs link layer switching at the UniPro, for example, L3 switching. The UFS device 6720 and the UFS card 6730 may communicate with each other through link layer switching of the switching module 6740 at the UniPro, and the switching module 6740 may be integrated as one module with the UFS device 6720 inside or outside the UFS device 6720. A configuration in which one UFS device 6720 and one UFS card 6730 are connected to the switching module 6740 is provided by way of example for convenience of description. However, a plurality of modules each including the switching module 6740 and the UFS device 6720 may be connected in parallel or in the form of a star to the host 6710 or connected in series or in the form of a chain to each other. Furthermore, a plurality of UFS cards may be connected in parallel or in the form of a star to the UFS device 6720.

In the UFS system 6800 illustrated in FIG. 16, each of the host 6810, the UFS device 6820 and the UFS card 6830 may include M-PHY and UniPro. The UFS device 6820 may perform a switching operation in order to communicate with the host 6810 and the UFS card 6830. In particular, the UFS device 6820 may communicate with the host 6810 or the UFS card 6830 through a switching operation between the M-PHY and UniPro module for communication with the host 6810 and the M-PHY and UniPro module for communication with the UFS card 6830, for example, through a target ID (Identifier) switching operation. The host 6810 and the UFS card 6830 may communicate with each other through target ID switching between the M-PHY and UniPro modules of the UFS device 6820. A configuration in which one UFS device 6820 is connected to the host 6810 and one UFS card 6830 is connected to the UFS device 6820 is provided by way of example for convenience of description. However, a plurality of UFS devices may be connected in parallel or in the form of a star to the host 6810, or connected in series or in the form of a chain to the host 6810, and a plurality of UFS cards may be connected in parallel or in the form of a star to the UFS device 6820, or connected in series or in the form of a chain to the UFS device 6820.

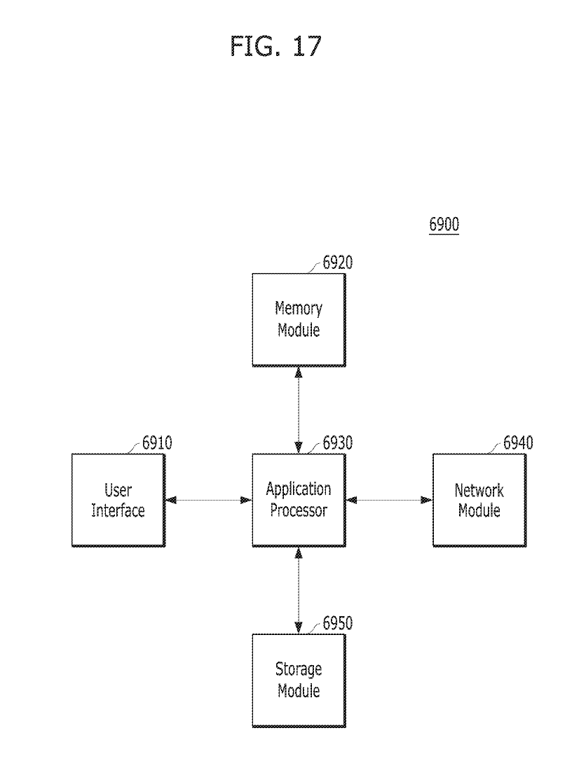

FIG. 17 is a diagram schematically illustrating another example of the data processing system including the memory system in accordance with an embodiment. FIG. 17 is a diagram schematically illustrating a user system to which the memory system may be applied.

Referring to FIG. 17, the user system 6900 may include an application processor 6930, a memory module 6920, a network module 6940, a storage module 6950 and a user interface 6910.

More specifically, the application processor 6930 may drive components included in the user system 6900, for example, an OS, and include controllers, interfaces and a graphic engine which control the components included in the user system 6900. The application processor 6930 may be provided as System-on-Chip (SoC).

The memory module 6920 may be used as a main memory, work memory, buffer memory or cache memory of the user system 6900. The memory module 6920 may include a volatile RAM such as DRAM, SDRAM, DDR SDRAM, DDR2 SDRAM, DDR3 SDRAM, LPDDR SDARM, LPDDR3 SDRAM or LPDDR3 SDRAM or a nonvolatile RAM such as PRAM, ReRAM, MRAM or FRAM. For example, the application processor 6930 and the memory module 6920 may be packaged and mounted, based on POP (Package on Package).

The network module 6940 may communicate with external devices. For example, the network module 6940 may not only support wired communication, but also support various wireless communication protocols such as code division multiple access (CDMA), global system for mobile communication (GSM), wideband CDMA (WCDMA), CDMA-2000, time division multiple access (TDMA), long term evolution (LTE), worldwide interoperability for microwave access (Wimax), wireless local area network (WLAN), ultra-wideband (UWB), Bluetooth, wireless display (WI-DI), thereby communicating with wired/wireless electronic devices or particularly mobile electronic devices. Therefore, the memory system and the data processing system, in accordance with an embodiment of the present invention, can be applied to wired/wireless electronic devices. The network module 6940 may be included in the application processor 6930.

The storage module 6950 may store data, for example, data received from the application processor 6930, and then may transmit the stored data to the application processor 6930. The storage module 6950 may be embodied by a nonvolatile semiconductor memory device such as a phase-change RAM (PRAM), a magnetic RAM (MRAM), a resistive RAM (ReRAM), a NAND flash, NOR flash and 3D NAND flash, and provided as a removable storage medium such as a memory card or external drive of the user system 6900. The storage module 6950 may correspond to the memory system 110 described with reference to FIG. 1. Furthermore, the storage module 6950 may be embodied as an SSD, eMMC and UFS as described above with reference to FIGS. 11 to 16.

The user interface 6910 may include interfaces for inputting data or commands to the application processor 6930 or outputting data to an external device. For example, the user interface 6910 may include user input interfaces such as a keyboard, a keypad, a button, a touch panel, a touch screen, a touch pad, a touch ball, a camera, a microphone, a gyroscope sensor, a vibration sensor and a piezoelectric element, and user output interfaces such as a liquid crystal display (LCD), an organic light emitting diode (OLED) display device, an active matrix OLED (AMOLED) display device, an LED, a speaker and a motor.

Furthermore, when the memory system 110 of FIG. 1 is applied to a mobile electronic device of the user system 6900, the application processor 6930 may control overall operations of the mobile electronic device, and the network module 6940 may serve as a communication module for controlling wired/wireless communication with an external device. The user interface 6910 may display data processed by the processor 6930 on a display/touch module of the mobile electronic device, or support a function of receiving data from the touch panel.

According to embodiments of the present invention, a memory system and an operating method of the memory system are capable of processing data with a memory device quickly and stably by minimizing the complexity and performance deterioration of the memory system and maximizing the utility efficiency of the memory device.

While the present invention has been described with respect to specific embodiments, it will be apparent to those skilled in the art in light of this disclosure that various changes and modifications may be made without departing from the spirit and scope of the invention as defined in the following claims.

What is claimed is:

1. A memory system, comprising:
a memory device that includes a plurality of memory blocks, each of which includes a plurality of pages that store data; and
a controller suitable for checking erase states of the plurality of memory blocks, performing a foreground operation and a background operation on the plurality of memory blocks based on the erase states, and storing the erase states in the plurality of memory blocks as checkpoint information.

2. The memory system of claim 1, wherein the controller checks erase voltage distribution or erase voltage offset distribution of a monitoring zone set in each of the plurality of memory blocks and checks the erase states through the respective erase voltage distributions or the erase voltage offset distributions.

3. The memory system of claim 2, wherein the monitoring zone is set in a last word line among a plurality of word lines in each of the plurality of memory blocks or in a last page among a plurality of pages in each of the plurality of memory blocks.

4. The memory system of claim 2, wherein the controller performs a read operation through a change of a read voltage in the monitoring zone of each of the plurality of memory blocks, and checks the erase voltage distributions or the erase voltage offset distributions in the plurality of memory blocks through the read operations.

5. The memory system of claim 2, wherein the controller provides an erase check command for the monitoring zone of each of the plurality of memory blocks to the memory device, and checks the erase voltage distributions or the erase voltage offset distributions in the plurality of memory blocks through the erase check commands.

6. The memory system of claim 2, wherein the controller copies and stores data stored in first memory blocks among the plurality of memory blocks into second memory blocks, based on the respective erase voltage distributions or the erase voltage offset distributions in the first memory blocks.

7. The memory system of claim 6, wherein the controller processes the first memory blocks as closed memory blocks, and performs program operations corresponding to write commands on the second memory blocks in response to receiving the write commands for the first memory blocks.

8. The memory system of claim 2, wherein the controller stores data corresponding to write commands in first memory blocks among the plurality of memory blocks, based on the respective erase voltage distributions or the erase voltage offset distributions in the first memory blocks.

9. The memory system of claim 1, wherein after performing erase operations corresponding to erase commands on first memory blocks among the plurality of memory blocks, the controller checks the erase states in the first memory blocks, and before performing program operations corresponding to write commands on second memory blocks, the controller checks the erase states in the second memory blocks.

10. The memory system of claim 1, wherein the controller checks the erase states in the plurality of memory blocks after the memory system changes from a power-off state to a power-on state.

11. An operating method of a memory system, comprising:
in a memory device that includes a plurality of memory blocks, each of which includes a plurality of pages that store data,
checking erase states of the plurality of memory blocks;
performing a foreground operation and a background operation on the plurality of memory blocks based on the erase states; and
storing the erase states in the plurality of memory blocks as checkpoint information.

12. The operating method of claim 11, wherein the checking of the erase states of the plurality of memory blocks includes:
checking erase voltage distribution or erase voltage offset distribution of a monitoring zone set in each of the plurality of memory blocks; and
checking the erase states through the respective erase voltage distributions or the erase voltage offset distributions.

13. The operating method of claim 12, wherein the monitoring zone is set in a last word line among a plurality of word lines in each of the plurality of memory blocks or in a last page among a plurality of pages in each of the plurality of memory blocks.

14. The operating method of claim 12, wherein the checking of the erase voltage distribution or the erase voltage offset distribution includes:
performing a read operation through a change of a read voltage in the monitoring zone of each of the plurality of memory blocks; and
checking the erase voltage distribution or the erase voltage offset distribution of each of the plurality of memory blocks through the corresponding read operation.

15. The operating method of claim 12, wherein the checking of the erase voltage distribution or the erase voltage offset distribution includes:
providing erase check commands for the monitoring zones to the memory device; and
checking the erase voltage distributions or the erase voltage offset distributions through the erase check commands.

16. The operating method of claim 12, wherein the performing of the foreground operation and the background operation on the plurality of memory blocks based on the erase states includes:
copying and storing data stored in first memory blocks among the plurality of memory blocks into second memory blocks based on the respective erase voltage distributions or the erase voltage offset distributions in the first memory blocks.

17. The operating method of claim 16, wherein the performing of the foreground operation and the background operation on the plurality of memory blocks based on the erase states includes:
processing the first memory blocks as closed memory blocks; and
performing program operations corresponding to write commands on the second memory blocks in response to receiving the write commands for the first memory blocks.

18. The operating method of claim 12, wherein the performing of the foreground operation and the background operation on the plurality of memory blocks based on the erase states includes:
storing data corresponding to write commands in first memory blocks among the plurality of memory blocks based on the respective erase voltage distributions or the erase voltage offset distributions in the first memory blocks.

19. The operating method of claim 11, wherein the checking of the erase states of the plurality of memory blocks includes:
after performing erase operations based on erase commands on first memory blocks among the plurality of memory blocks, checking the erase states in the first memory blocks; and
before performing program operations corresponding to write commands on second memory blocks, checking the erase states in the second memory blocks.

20. The operating method of claim 11, wherein the checking of the erase states of the plurality of memory blocks includes:
checking the erase states in the plurality of memory blocks after the memory system changes from a power-off state to a power-on state.

21. A memory system comprising:
a memory device including at least one memory block having a monitoring zone; and
a controller suitable for controlling, when an erase voltage distribution of the monitoring zone is below a threshold, the memory device to copy data of the memory block into a normal memory block and to close the memory block,
wherein the controller stores information of the erase voltage distribution of the monitoring zone as checkpoint information.
